(19) United States
(12) Patent Application Publication
(10) Pub. No.: US 2024/0290910 A1
(43) Pub. Date: Aug. 29, 2024

(54) PROCESSES FOR FABRICATING MICROLEDS ON TRANSPARENT BACKPLANE

(71) Applicant: Lumileds LLC, San Jose, CA (US)

(72) Inventors: Mukul Agrawal, Fremont, CA (US); Zhongmin Ren, Danville, CA (US); Grigoriy Basin, San Francisco, CA (US)

(21) Appl. No.: 18/584,408

(22) Filed: Feb. 22, 2024

Related U.S. Application Data
(60) Provisional application No. 63/448,170, filed on Feb. 24, 2023.

(51) Int. Cl. H01L 33/00; H01L 25/075; H01L 33/52; H01L 33/62

(52) U.S. Cl. CPC H01L 33/0095; H01L 25/0753; H01L 33/52; H01L 33/62; H01L 2933/0066

(57) ABSTRACT

A method of forming one or more transparent microLED light sources comprises providing a flexible transparent sheet on which are disposed a plurality of inorganic microLEDs and conductive paths configured to power the plurality of inorganic microLEDs, positioning a solid transparent sheet of adhesive between the flexible transparent sheet and a transparent substrate, and bonding the transparent sheet of adhesive to the flexible transparent sheet and to the transparent substrate to form a laminated structure. The conductive paths and the microLEDs are arranged to form at least one sparse microLED array.

### RELATED APPLICATION

This application claims priority to U.S. Provisional Patent Application No. 63/448,170 titled “Transparent MicroLED Illuminator Integration with Eyewear” and filed on Feb. 24, 2023, which is incorporated by reference herein in its entirety.

### FIELD OF THE INVENTION

The invention relates generally to transparent microLED illuminators and methods for manufacturing them, and more particularly to methods and apparatus that integrate a transparent infrared microLED illuminator with eyewear through which a user may view a real or virtual scene.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors.

Inorganic LEDs and pcLEDs have been widely used to create different types of displays, including displays for mobile phones, smart watches, smart glasses, monitors and TVs, augmented-reality (AR) displays, virtual-reality (VR) displays, and mixed-reality (MR) displays. Inorganic LEDs and pcLEDs have also been widely used for illumination. Individual LEDs or pcLEDs in these architectures can have an area of a few square millimeters down to a few square micrometers (e.g., microLEDs).

This specification refers to LEDs and pcLEDs collectively as “LEDs.”

### SUMMARY

This specification discloses transparent microLED light sources (also referred to herein as illuminators) and methods for manufacturing them. As used in this specification, transparent is intended to mean that the transparent light source allows light to pass through so that a scene (e.g., real or presented on a display) behind the light source can be distinctly seen through the light source. This may be accomplished for example by using sufficiently sparse arrays (e.g., center to center pitch of ≥80 μm between microLEDs or between pairs or small groups of microLEDs) of sufficiently small microLEDs (e.g., side lengths of 2 microns to 50 microns or 2 microns to 20 microns) arranged on a transparent substrate. Conductive paths providing power and/or control signals to the microLEDs may be, for example, transparent or sufficiently thin (e.g., width≤30 μm) to not obstruct the view through the light source. For such a transparent light source the microLEDs and the conductive paths are generally not noticeable or are easily overlooked by a person looking through or at the light source, for example analogously to dust on an eyeglass lens.

The transparent light sources disclosed herein may comprise visible light emitting and/or infrared light emitting microLEDs. Visible light emitting microLEDs, if present, may be arranged to display information to a user. Infrared light emitting microLEDs, if present, may be arranged to detect information about a user, for example as part of a system that tracks a user's eye motion to determine the direction in which a user's eyes are looking (i.e., the direction of the user's gaze). The visible light emitting microLEDs may be phosphor converted microLEDs or direct emitting (i.e., not phosphor converted) microLEDs. The infrared light emitting microLEDs may be phosphor converted microLEDs or directed emitting microLEDs.

This specification focuses on the integration of transparent infrared microLED light sources with eyewear, with the infrared emitting microLEDs arranged to be used to track a user's eye motion as just described. Such eyewear may be used, for example, in AR, MR, and VR systems. The eyewear may optionally include a transparent display comprising visible light emitting microLEDs integrated with the transparent infrared microLED light source. Alternatively, the eyewear may include an (optionally transparent) display provided separately from (not integrated with) the transparent microLED light source, for example positioned to be viewed by the user through the transparent infrared microLED light source. As yet another alternative, such eyewear may lack any visible light display to be viewed by a user.

Although this specification focuses on the integration of transparent (e.g., infrared) microLED light sources with eyewear, the transparent microLED light sources and manufacturing methods disclosed herein may be readily used in other technical and commercial applications.

In one aspect of the invention a method of forming transparent microLED light sources comprises preparing or obtaining a flexible transparent sheet on which are disposed a plurality of inorganic microLEDs and conductive paths configured to provide electrical signals that power and control the plurality of inorganic microLEDs, positioning a solid transparent sheet of adhesive between the flexible transparent sheet and a transparent substrate, and bonding the transparent sheet of adhesive to the flexible transparent sheet and to the transparent substrate to form a laminated structure. The conductive paths and the microLEDs are arranged on the flexible transparent sheet to form at least one sparse microLED array. The assembly comprising the flexible transparent sheet and the conductive paths may be referred to herein as a thin transparent electrical backplane.

The conductive paths and the microLEDs may be arranged on the transparent flexible sheet to form two or more independently operable and spatially separated sparse microLED arrays.

The microLEDs may be visible light emitting microLEDs, infrared light emitting microLEDs, or a mixture of visible light emitting microLEDs and infrared light emitting microLEDs.

The method may comprise bonding the transparent sheet of adhesive to the flexible transparent sheet prior to bonding the transparent sheet of adhesive to the transparent substrate. Alternatively the method may comprise bonding the transparent sheet of adhesive to the transparent substrate prior to bonding the transparent sheet of adhesive to the transparent flexible sheet.

The method may comprise creating or disposing the conductive paths on the flexible transparent sheet. Creating or disposing the conductive paths on the flexible transparent sheet may comprise electroplating conductive traces onto the flexible transparent sheet to form the conductive paths. Alternatively, or in addition, creating or disposing the conductive paths on the flexible transparent sheet may comprise coating the flexible transparent sheet with a transparent conductive film (e.g., a conductive metal oxide such as Indium Tin Oxide, for example) and segmenting the transparent conductive film into electrically isolated regions to define the conductive paths.

The method may comprise disposing the microLEDs on the flexible transparent sheet. The microLEDs may be disposed on the flexible transparent sheet by conventional pick and place methods, for example, and may optionally be positioned as adjacent pairs of microLEDs to provide redundancy. Disposing the microLEDs on the flexible transparent sheet may comprise, for example, dispensing drops or lines of conductive glue at discrete locations on the conductive paths and bonding the microLEDs to the flexible transparent sheet with the drops or lines of conductive glue.

The method may comprise attaching the flexible transparent sheet to a carrier prior to disposing the microLEDs on the flexible transparent sheet and detaching the flexible transparent sheet from the carrier after bonding the transparent sheet of adhesive to the flexible transparent sheet and to the transparent substrate to form the laminated structure.

The method may comprise cutting from the laminated structure at least one transparent microLED light source comprising a sparse microLED array.

In variations in which the conductive paths and the microLEDs are arranged on the transparent flexible sheet to form two or more independently operable and spatially separated sparse microLED arrays, the method may comprise cutting from the laminated structure two or more transparent microLED light sources, with each of the transparent microLED light sources comprising at least one of the independently operable and spatially separated sparse microLED arrays.

In variations in which the conductive paths and the microLEDs are arranged on the transparent flexible sheet to form two or more independently operable and spatially separated sparse microLED arrays, the method may comprise cutting from the laminated structure one or more transparent microLED light sources, with each of the transparent microLED light sources comprising two adjacent ones of the independently operable and spatially separated sparse microLED arrays.

In any of the above variations, the transparent microLED light sources may be cut from the laminated structure in a shape of a lens or window for eyewear.

In another aspect of the invention, a method of forming one or more transparent microLED light sources comprises preparing or obtaining a transparent laminated structure comprising a flexible transparent sheet on which are disposed a plurality of inorganic microLEDs and conductive paths configured to power the plurality of inorganic microLEDs, a transparent substrate, and a transparent sheet of adhesive positioned between and bonded to the flexible transparent sheet and the transparent substrate. The conductive paths and the microLEDs are arranged to form at least one sparse microLED array. The method further comprises cutting from the laminated structure at least one transparent microLED light source comprising a sparse microLED array.

The conductive paths and the microLEDs may be arranged on the transparent flexible sheet to form two or more independently operable and spatially separated sparse microLED arrays.

The microLEDs may be visible light emitting microLEDs, infrared light emitting microLEDs, or a mixture of visible light emitting microLEDs and infrared light emitting microLEDs.

In variations in which the conductive paths and the microLEDs are arranged on the transparent flexible sheet to form two or more independently operable and spatially separated sparse microLED arrays, the method may comprise cutting from the laminated structure two or more transparent microLED light sources, with each of the transparent microLED light sources comprising at least one of the independently operable and spatially separated sparse microLED arrays.

In variations in which the conductive paths and the microLEDs are arranged on the transparent flexible sheet to form two or more independently operable and spatially separated sparse microLED arrays, the method may comprise cutting from the laminated structure one or more transparent microLED light sources, with each of the transparent microLED light sources comprising two adjacent ones of the independently operable and spatially separated sparse microLED arrays.

In any of the above variations, the transparent microLED light sources may be cut from the laminated structure in a shape of a lens or window for eyewear.

In another aspect of the invention, a transparent laminated structure comprises a flexible transparent sheet on which are disposed a plurality of inorganic microLEDs and conductive paths configured to power the plurality of inorganic microLEDs, a transparent substrate, and a transparent sheet of adhesive positioned between and bonded to the flexible transparent sheet and the transparent substrate. The conductive paths and the microLEDs are arranged to form at least one sparse microLED array.

The conductive paths and the microLEDs may be arranged on the transparent flexible sheet to form two or more independently operable and spatially separated sparse microLED arrays.

The microLEDs may have side lengths in a plane of the laminated structure of, for example, about 2 microns to about 20 microns. Individual microLEDs, or pairs or small groups of microLEDs, may be spaced apart from each other with a center-to-center distance of, for example, greater than or equal to about 80 microns.

The conductive paths may comprise conductive traces having widths in the plane of the laminated structure of less than or equal to about 30 microns, for example. In addition, or alternatively, the conductive paths may comprise segmented portions of a conductive film disposed on the flexible transparent sheet.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1A shows a cross-sectional schematic view of an example eyewear lens or window (eyepiece) comprising a transparent microLED light source.

FIG. 1B shows a schematic plan view of the example eyepiece of FIG. 1A.

FIG. 1C shows an example schematic plan view of eyewear comprising two of the eyepieces of FIG. 1A.

FIG. 2A shows a plan view of a portion of an example transparent flexible backplane that may be used in a transparent microLED light source.

FIG. 2B shows a close-up schematic plan view of a portion of the example transparent flexible backplane of FIG. 2A.

FIG. 2C shows a close-up plan view of a peripheral portion of an example backplane through which power is provided to the backplane.

FIG. 2D shows a plan view of a portion of another example transparent flexible backplane that may be used in a transparent microLED light source.

FIGS. 3A, 3B, 3C, and 3D show steps in an example process flow for making one or more transparent microLED light sources.

FIGS. 4A, 4B, and 4C show steps in a variation of the example process flow shown in FIGS. 3A-3D.

FIGS. 5A, 5B, and 5C show steps in another variation of the example process flow shown in FIGS. 3A-3D.

FIG. 6 illustrates, by way of example, a diagram of an embodiment of a sparse microLED array.

FIG. 7 illustrates, by way of example, a diagram of an embodiment of a microLED array that includes six strings of microLEDs.

FIG. 8 illustrates, by way of example, an example of a microLED array with twelve strings of microLEDs.

FIG. 9 illustrates, by way of example, a nozzle dispensing a conductive adhesive about pads.

FIG. 10 illustrates, by way of example, the nozzle situated to grab a microLED.

FIG. 11 illustrates, by way of example, the microLED attached to the pads by the conductive adhesive.

FIG. 12 illustrates, by way of example operations of a technique for concurrent mass electrical connection of the microLEDs of a sparse array.

FIG. 13 shows a plan view of an example laminated structure from which a plurality of eyepieces such as that shown in FIG. 1B may be cut.

FIG. 14 shows an example variation in which a window for eyewear comprising two adjacent transparent microLED light sources is cut from a laminated structure such as that shown in FIG. 13.

FIG. 15 illustrates, by way of example, a diagram of an embodiment of a method for manufacturing a transparent, sparse microLED array.

### DETAILED DESCRIPTION

The following detailed description should be read with reference to the drawings, in which identical reference numbers refer to like elements throughout the different FIGs. The drawings, which are not necessarily to scale, depict selective embodiments and are not intended to limit the scope of the invention. The detailed description illustrates by way of example, not by way of limitation, the principles of the invention.

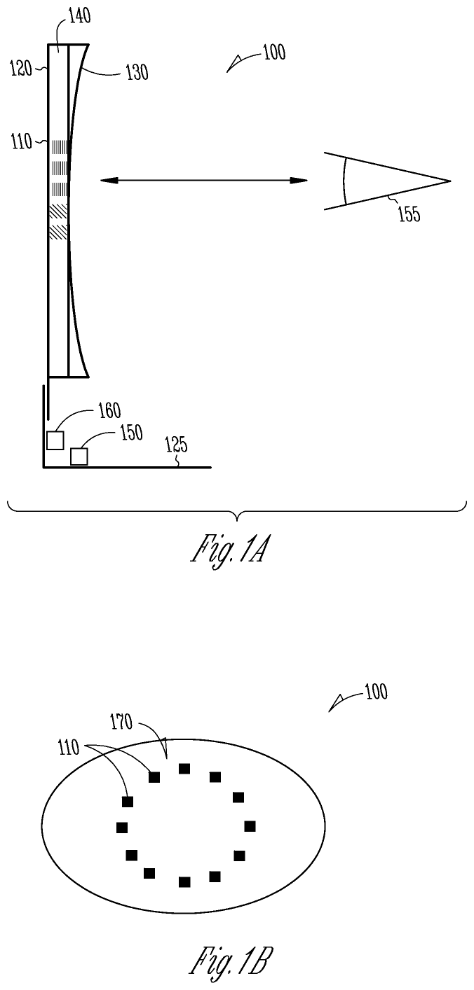

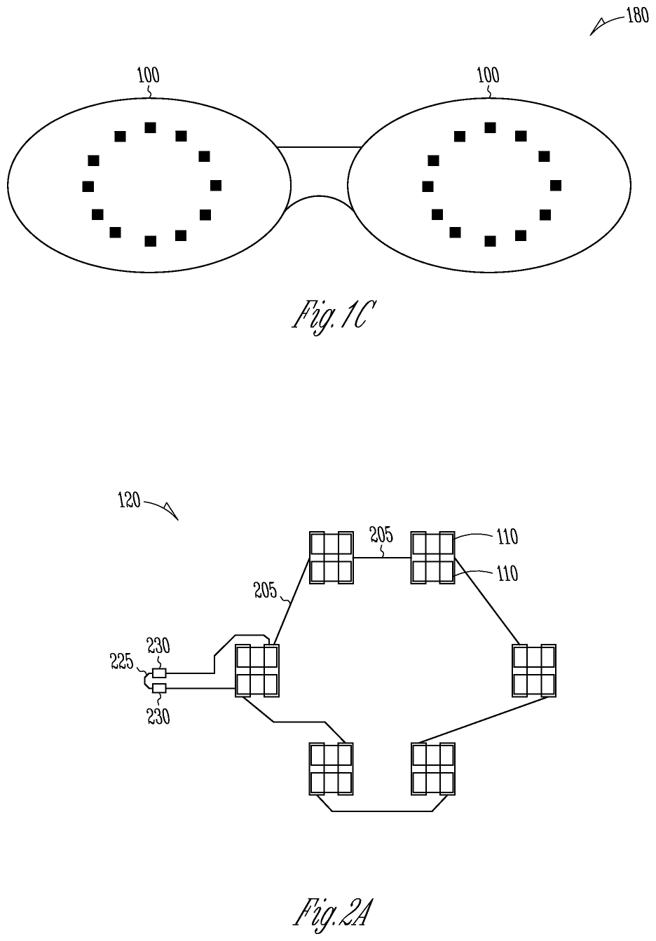

As summarized above, this specification discloses transparent microLED light sources and methods for manufacturing them and integrating them into eyewear. FIG. 1A shows a cross-sectional schematic view of an example lens or window (also referred to herein as an eyepiece) 100 for eyewear. Eyepiece 100 comprises a sparse array of microLEDs 110 disposed on a thin transparent electrical backplane 120 comprising conductive paths configured to provide electrical signals that power and control the microLEDs. While the microLEDs 110 are illustrated as being visible for explanation purposes, the microLEDs 110 are invisible to the human eye when in a sparse array. Light emitted from the microLEDs, however, can be in the visible spectrum and visible to the human eye. Backplane 120 is bonded to a transparent substrate 130 by a transparent adhesive 140 disposed between the backplane and the transparent substrate.

Electrical signals may be supplied to backplane 120 through a flex connector 125, for example through vias passing through backplane 120 to the conductive paths. As an alternative to vias, one or more wrap around electrodes may be disposed along one or more edges of backplane 120 to create a conductive connection between its opposing front and back sides. Wrap around electrodes may be dispensed using a variety of techniques including for example aerosol, inkjet, electrohydrodynamically controlled inkjet, screen printing, and chemical vapor deposition (CVD)/physical vapor deposition (PVD)/atomic layer deposition (ALD) coating and patterning.

Each microLED 110 comprise a semiconductor light emitting diode (LED) and optionally a wavelength converting structure that absorbs light emitted by the semiconducting LED and emits light of a longer wavelength (in which case the LED is a pcLED). The semiconductor light emitting diodes may be formed for example from II-VI, III-V, or other semiconductor material systems and may be configured to emit, for example, ultraviolet, visible, or infrared light, depending on the application.

The wavelength converting structures, if present, include one or more wavelength converting materials which may be, for example, conventional phosphors, ceramic phosphors, organic phosphors, quantum dots, organic semiconductors, II-VI or III-V semiconductors, II-VI or III-V semiconductor quantum dots or nanocrystals, dyes, polymers, or other materials that luminesce. The wavelength converting materials absorb light emitted by the LED and in response emit light of a longer wavelength. Phosphors or other wavelength converting materials may for example be dispersed as luminescent particles in a binder material such as a silicone, for example, to form a wavelength converting structure.

Transparent substrate 130 may be flat or curved in shape to provide a lens of any suitable power (including zero power) adapted for use with an eye 155 position at a conventional (e.g., 20 mm) distance from the window or lens.

Backplane 120 may be formed from a thin, transparent, flexible sheet of material such as, for example, transparent glass, colorless polyimide, or any other suitable material. The transparent flexible sheet may have a thickness of, for example about 50 microns to about 1000 microns. Transparent substrate 130 may be formed from, for example, polycarbonate, glass, or any other suitable material and may have any thickness suitable for a window or lens for eyewear. For example, transparent substrate 130 may have a thickness of about 0.5 millimeters to about 5 millimeters. The backplane 120 can be formed on a transparent flexible material that is sufficiently flexible to accommodate curvature (if present) of the surface of transparent substrate 130 to which it is bonded without cracking or otherwise failing.

Transparent adhesive 140 may be a silicone glue, for example, and may have a thickness of, for example, about 2 microns to about 200 microns.

A controller 150 can include a microcontroller, application specific integrated circuit (ASIC), field programmable gate array (FPGA), central processing unit (CPU), logic gates (e.g., AND, OR, XOR, negate, buffer, or the like), a combination thereof or the like. The controller 150 can provide control signals to driver circuits 160. The driver circuits 160 can include pulse width modulation (PWM) circuitry configured to drive the microLEDs 110 with a driving current. The driving current can cause the microLEDs 110 to generate visible, infrared, or other light at a specified intensity. The intensity can provide an image, a flood, or glint that can be used for image generation or eye tracking, for example.

FIG. 1B shows a schematic plan view of example eyepiece 100 from FIG. 1A. In the illustrated example eyepiece 100 is ovular in shape, but any suitable shape may be used. In the illustrated example microLEDs 110 are arranged in a peripheral group 170. Peripheral group 170 is arranged so that each microLED 110 in the group is in peripheral vision (not directly in front of the eye). In an application in which the microLEDs are infrared emitting microLEDs employed to track the eye motion and gaze direction, the peripheral group 170 of infrared microLEDs may for example provide glint or flood or otherwise modulated illumination of the user's eye. Any other spatial distribution of flood or glint and modulated infrared microLEDs suitable for eye tracking may also be used. More generally, any suitable spatial distribution of infrared and/or visible light emitting microLEDs may be used depending on the application for the transparent microLED light source.

Note that in the illustrated examples the size of microLEDs 110 is exaggerated for clarity of explanation. As explained above in the summary, typically the size and spacing of the microLEDs is chosen to make the microLED light source transparent and to make the microLEDs and the conductive paths that provide power to the microLEDs, invisible, un-noticed or easily overlooked by a casual observer.

FIG. 1C shows an example schematic plan view of eyewear 180 comprising two eyepieces 100. Each eyepiece 100 comprises an array of microLEDs as described above.

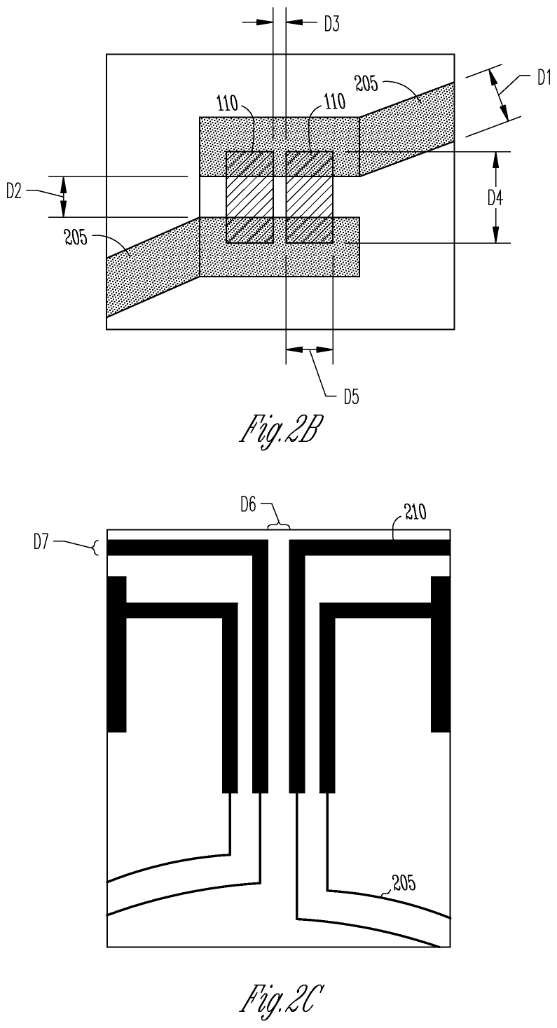

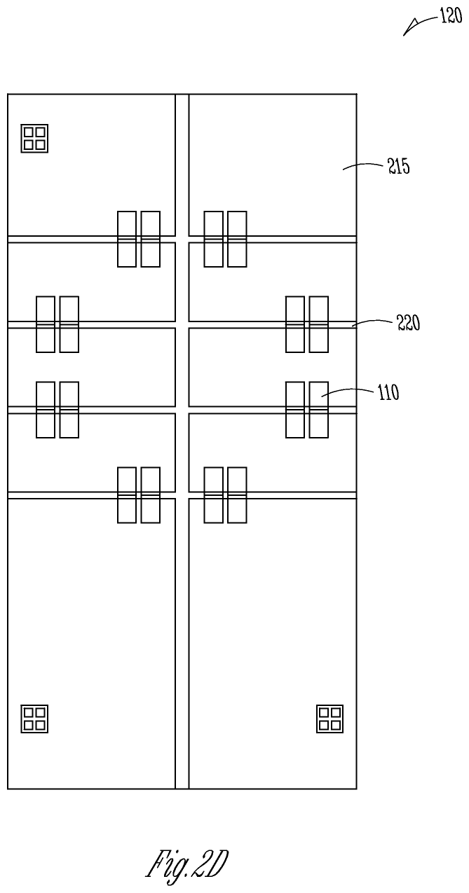

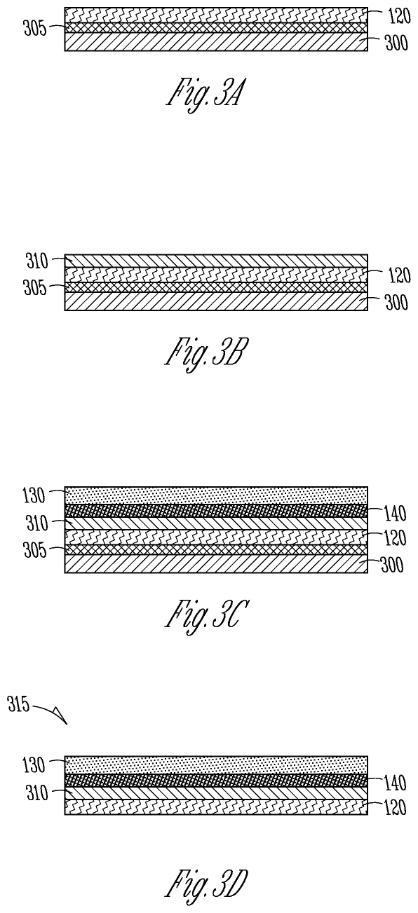

FIG. 2A shows a plan view of a portion of an example backplane 120 comprising conductive traces 205 arranged to provide power or other electrical signals to microLEDs 110. In the illustrated example microLEDs 110 are arranged in parallel pairs, with the microLEDs in a pair electrically connected in parallel to provide redundancy in the event one or the other of the microLEDs is defective or fails. In the example of FIG. 2A, the microLEDs 110 are arranged in a single string, but other arrangements of microLEDs are possible and anticipated by embodiments herein.

A temporary trace 225 can short driver pads 230 of the sparse microLED array on the backplane 120. The trace 225 helps protect the microLEDs 110 from electrostatic discharge (ESD) events. The trace 225, or a portion thereof, can be removed during singulation of the eyepieces from a carrier or wafer.

In the illustrated example the pairs of microLEDs are arranged in two strings. Each string comprises four pairs of (parallel connected) microLEDs connected in series by conductive traces 205. As noted above, any other suitable spatial arrangement of microLEDs and conductive traces and corresponding electrical connectivity may be used instead.

FIG. 2B shows a close-up schematic plan view of a pair of parallel connected microLEDs 110 and associated conductive traces 205 from the example of FIG. 2A. In this example, the conductive traces 205 have widths of D1 ˜30 microns and are spaced apart to form a gap having a width D2 ˜20 microns which is spanned by microLEDs 110. MicroLEDs 110 have lengths D4 ˜ 46 microns and widths D5 ˜ 23 microns and are spaced apart from each other by D3 ˜ 7 microns. Any other suitable dimensions may be used instead.

FIG. 2C shows a close-up plan view of a peripheral portion of an example backplane 120. Conductive traces 205 are arranged on one side of the transparent backplane to provide power to microLEDs as described above. Metal pads 210 are arranged on an opposite side of the transparent backplane and are connected to respective ones of conductive traces 205 through conductive vias (not shown) passing through the backplane 120. Metal pads 210 may be used for example to electrically connect to a flex connector (e.g., flex connector 125 in FIG. 1A) to provide power to backplane 120. The electrical connections to the flex connector may be made for example using an anisotropic conductive film as a conductive adhesive. In the illustrated example metal pads 210 are spaced apart from each other by D6 ˜ 600 microns and have widths of D7 ˜ 400 microns. Any other suitable dimensions may be used instead.

Conductive traces 205 and metal pads 210 may be deposited on backplane 120 by electroplating, for example, or by any other suitable method.

As an alternative to conductive traces, as shown in FIG. 2D, the conductive paths providing power to the microLEDs may be formed by a segmented transparent conductive film. In the illustrated example, a transparent conductive oxide layer (e.g., Indium Tin Oxide) 215 on backplane 120 is segmented by (e.g., laser cut) trenches 220 into electrically isolated regions. Trenches 220 may have widths approximately equal to, somewhat wider, or somewhat narrower than a gap between cathode and anode pads on the microLEDs, for example. In the illustrated example the segmentation geometry is chosen to provide a circuit of series connected sites at which microLEDs 110 (or pairs of microLEDs 110, as shown) can be arranged to bridge the trenches 220 to form a series connected string of microLEDs or pairs of microLEDs. The electrically isolated regions of the segmented film provide conductive paths equivalent to those that might otherwise be provided by conductive traces. Any other suitable segmentation of a conductive film, arrangement of microLEDs, and corresponding electrical connectivity may be used instead.

For example, microLEDs may be interconnected across the trenches on the conductive film with specific orientations to create a mix of parallel and series electrical connections among the microLEDs. The conductive film may be segmented to create at least one (and in other embodiments more than one) set of separated anode and cathode pads. The conductive film may be segmented to design the flow of electricity from an anode pad on the film (for example Ground, in FIG. 2D) to a cathode pad on the film (for example Positive, in FIG. 2D) while passing through an electrically series connected sets of sites each of which may host a plurality of parallel connected LEDs across the site.

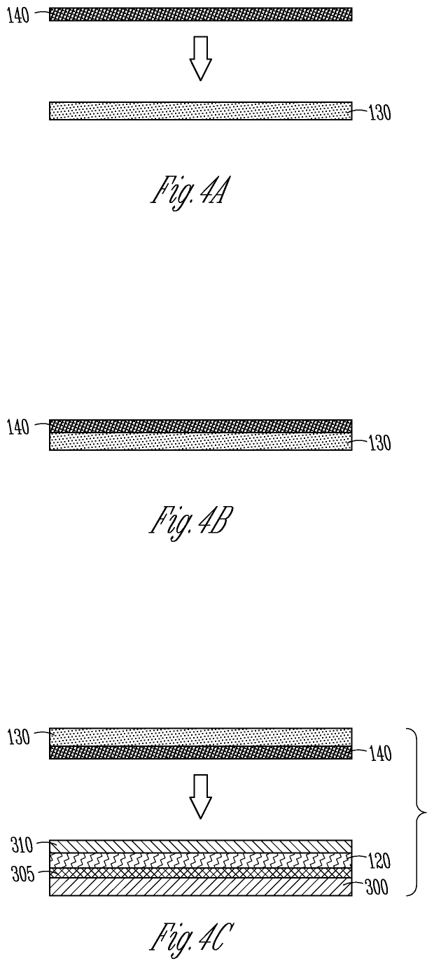

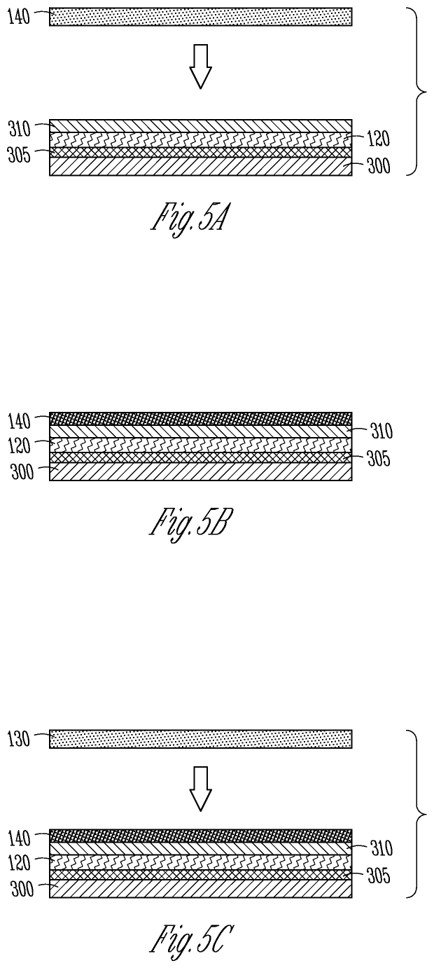

FIGS. 3A-3D show steps in an example process flow for making one or more transparent microLED light sources. In FIG. 3A a thin, transparent, flexible electrical backplane 120 as described above is (optionally) attached to a carrier 300 by dual layer thermal release tape 305. Carrier 300 is more rigid than backplane 120 and thereby makes backplane 120 easier to manage and work with. Carrier 300 may be formed from glass, for example.

In FIG. 3B dots of conductive glue (not shown) may be dispensed on backplane 120 at discrete locations along the conductive paths, and then microLEDs (not shown) bonded to backplane 120 with the dots of conductive glue. The microLEDs can be bonded individually, such as by using a nozzle. The nozzle can be coupled to a vacuum that produces a suction through the nozzle. The nozzle can be located proximate an individual microLED. The vacuum can be powered on to generate a vacuum pressure. The nozzle can then be located over a location with conductive glue. The vacuum pressure can then be released, such as by turning off the vacuum or otherwise reducing the vacuum pressure to release the microLED onto the conductive glue. The nozzle can then be repeated by locating the nozzle over another microLED and proceeding to place the microLED. Multiple nozzles can operate concurrently to place multiple microLEDs at the same time.

The resulting microLED array bonded to backplane 120 is represented in the FIG. by microLED layer 310. Separate conductive glue dots may be dispensed for each cathode and anode pad of each microLED before placing the microLEDs on the locations. A common glue dot or a glue line may be dispensed for a series of anode and cathode pads. The conductive glue may be or comprise an anisotropically-conductive material. After placing the LED(s), a thermal curing process, laser curing process, or a combination of such curing processes may be performed to activate anisotropic conduction material such that current only conducts in a direction perpendicular to the plane of the assembly and not in the plane of the assembly. The conductive glue may be dispensed using, for example, a variety of techniques including for example aerosol, inkjet, electrohydrodynamically controlled inkjet, screen printing, and spin coating and patterning.

In FIG. 3C a transparent substrate 130 as described above is bonded to microLED layer 310 and backplane 120 with a transparent adhesive 140 as described above. In FIG. 3D optional carrier 300 (if present) is removed using thermal release tape 305.

As shown in FIG. 3D this process flow results in a laminated structure 315 comprising a flexible transparent sheet (backplane 120) on which are disposed a plurality of inorganic microLEDs (microLED layer 310) and conductive paths configured to power the plurality of inorganic microLEDs, a transparent substrate 130, and a transparent sheet of adhesive 140 positioned between and bonded to the flexible transparent sheet and the transparent substrate. The conductive paths and the microLEDs may be arranged on backplane 120 to form at least one sparse microLED array.

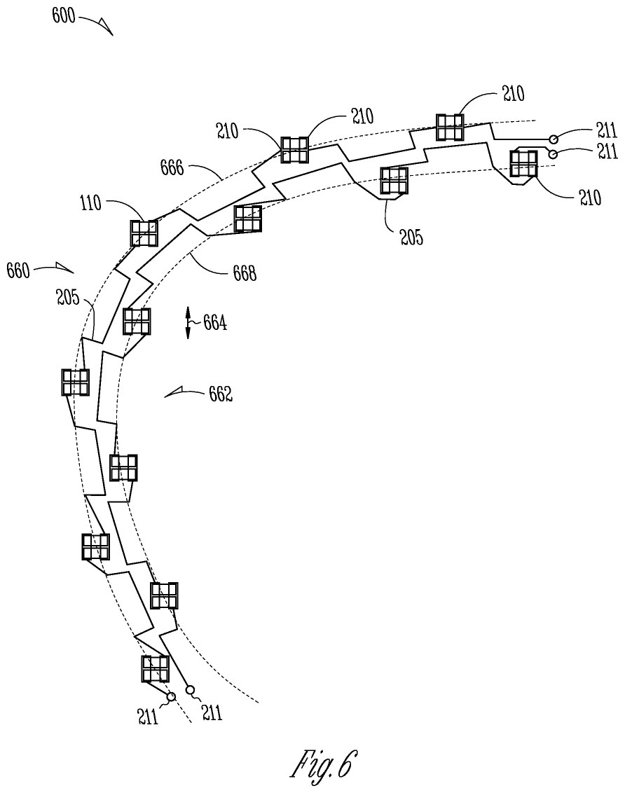

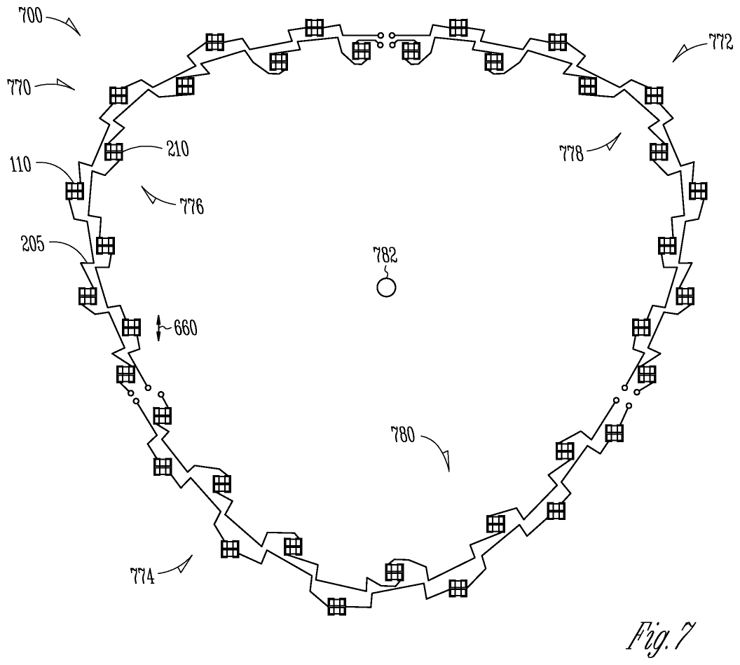

FIGS. 4A-4C show steps in a variation of the example process flow shown in FIGS. 3A-3D. In FIG. 4A transparent adhesive 140 is bonded to transparent substrate 130 to form the structure shown in FIG. 4B. In FIG. 4C the structure shown in FIG. 4B is bonded to the structure shown in FIG. 3B using transparent adhesive 140 to form the structure shown in FIG. 3C.

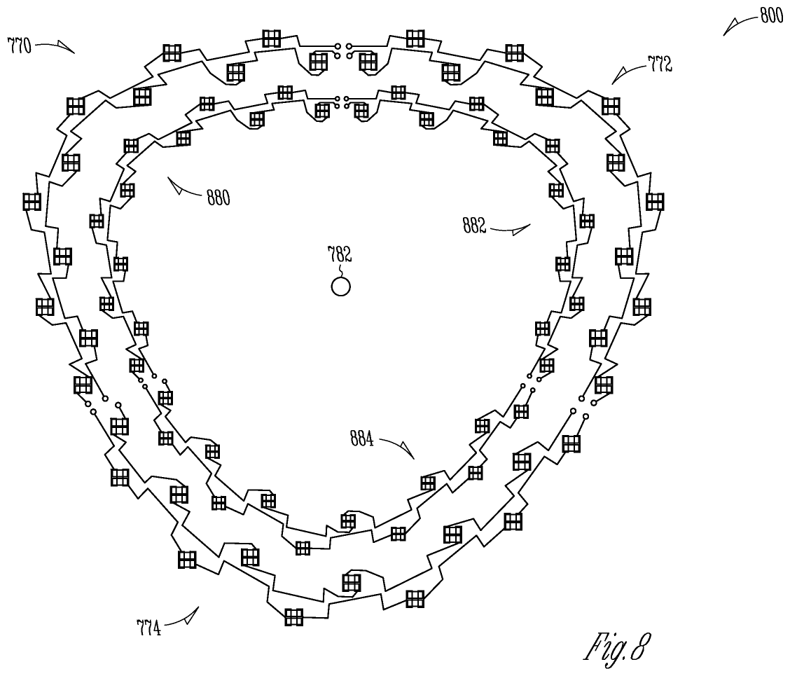

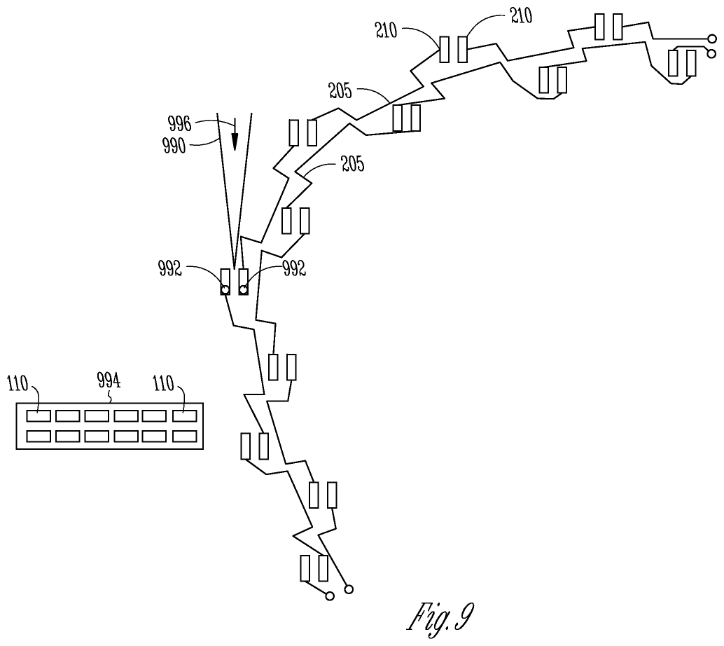

FIGS. 5A-5C show steps in another variation of the example process flow shown in FIGS. 3A-3D. In FIG. 5A transparent adhesive 140 is bonded to the structure shown in FIG. 3B to form the structure shown in FIG. 5B. In FIG. 5C transparent substrate 130 is bonded to the structure shown in FIG. 5B using adhesive 140 to form the structure shown in FIG. 3C.

FIG. 6 illustrates, by way of example, a diagram of an embodiment of a sparse microLED array 600. The microLED array 600 includes two strings 660, 662 of microLEDs 110. Each of the strings 660, 662 includes microLEDs 110 arranged about an arc 666. The arc 666 can include a constant or variable radius of curvature, can be a portion of an ellipse, a combination thereof, or the like. The pads 210 of the microLEDs 110 of a given string 660, 662 are electrically connected in series. Each of the strings 660, 662 is illustrated as including six microLEDs 110 each, but can include more or fewer microLEDs 110. Each pair of pads 210 is illustrated as including two microLEDs 110 electrically connected thereto. More or fewer microLEDs 110 can be electrically connected to each pair of pads 210. The microLEDs 110 electrically coupled to each pair of pads 210 is electrically connected in parallel to each other. Each of the microLEDs 1110 can be oriented in a same direction.

The traces 205 of each of the strings 660, 662 can meander about the respective arc 666, 668. The traces 205 can include a repeating, curving, square wave shape with alternating peaks and troughs. The microLEDs 110 on the string 660 that is further from an origin of the radius of curvature of the arcs 666, 668 can have microLEDs 110 situated on peaks of the square wave shape of the traces 205. The microLEDs 110 on the string 662 that is closer to an origin of the of the radius of curvature of the arcs 666, 668 can have microLEDs 110 situated on troughs of the square wave shape. Note that while a square wave shape is shown, other wave shapes with troughs and peaks, such as a sine wave or the like, can be used. Having microLEDs 110 in peaks in one string and troughs in a partnered string allows the microLEDs 110 to be disbursed and remain sparse enough to be imperceptible to the human eye when they are not emitting visible light.

Each of the strings terminates at a via 211 or other electrical connection. The number of microLEDs 110 in a given array can be selected so as to keep an electrical parameter within a specified range. The electrical parameter can be a voltage, current, or the like. The more microLEDs 110 that are in a given string the bigger the voltage drop across the string and the larger the current draw.

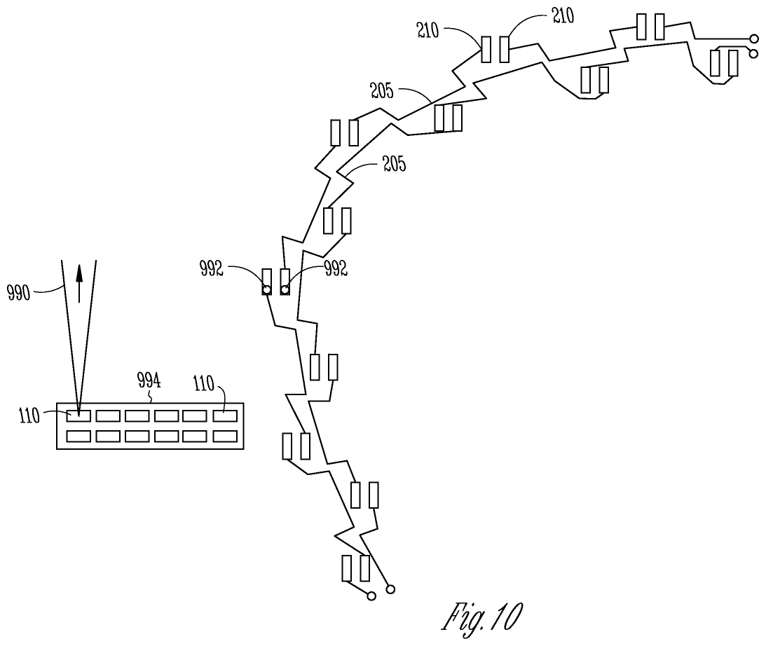

FIG. 7 illustrates, by way of example, a diagram of an embodiment of a microLED array 700 that includes six strings 770, 772, 774, 776, 778, 780 of microLEDs 110. The strings 770 and 776, 772 and 778, and 774 and 780 can be paired such that the microLEDs of the strings 770, 772, and 774 are on respective peaks of the traces 205 of the corresponding strings and the microLEDs of the strings 776, 778, and 780 are on respective troughs of the traces 205 of the corresponding strings. A combination of the strings 770, 772, 774 can encircle, encompass, or surround the strings 776, 778, 780. The combination of strings 770, 772, 774 can encircle, encompass, or surround a central point 782. The central point 782, which is just for illustrative purposes and not actual structure, indicates a point towards which a user of eyewear will look when gazing directly forward while wearing eyewear that includes the microLED array 700.

Since the pads 210 are all oriented the same (indicated by arrow 664) to receive microLEDs 110 oriented the same direction, the pads 210 are arranged so as to intersect an arc, and the traces 205 meander to follow the pads 210, an angle between the direction of the traces 205 connected to the pads 210 and the longitudinal axis of the pads 210 can vary to accommodate the arc 666, 668 (see FIG. 6).

The array 700 of FIG. 7 includes three strings combined to encircle, encompass, or surround the central point 782, more or fewer strings can combine to encircle, encompass, or surround the central point 782.

FIG. 8 illustrates, by way of example, an example of a microLED array 800 with twelve strings of microLEDs. An outer set of microLED strings 770, 772, 774 (and their corresponding strings with microLEDs in troughs that do not have reference labels so as to not obscure the view of the FIG.) can be used for glint or flood and an inner set of microLED strings 880, 882, 884 (and their corresponding strings with microLEDs in peaks that do not have reference labels so as to not obscure the view of the FIG.) can be used for the other of flood or glint. Both of the outer and the inner sets of microLED strings can encircle, encompass, or surround the central point 782 with the inner set of microLED strings being closer to the central point 782 than the outer set of microLEDs.

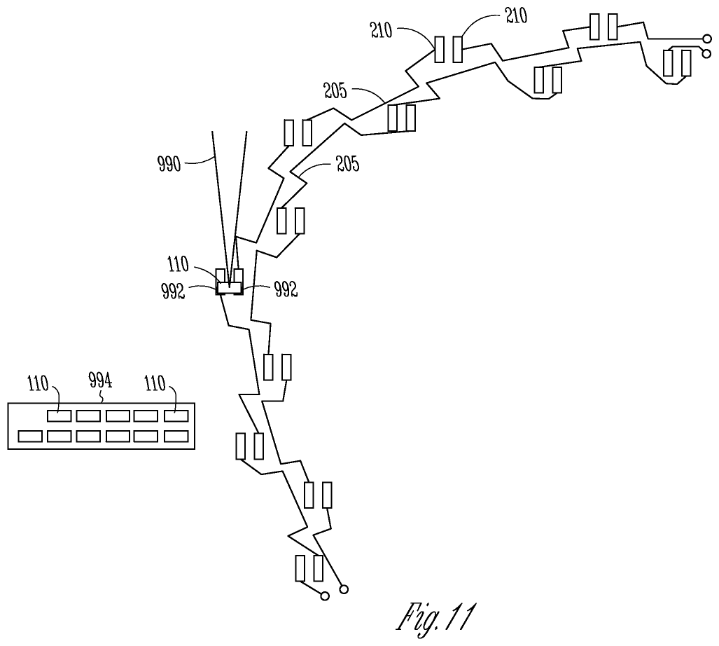

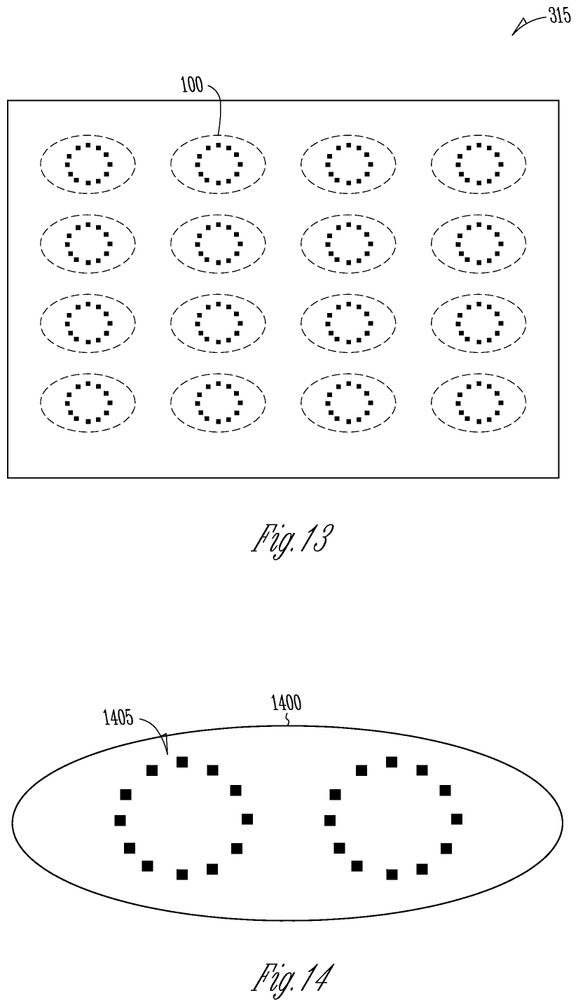

The microLEDs of any of the sparse arrays, such as any of the arrays disclosed herein, can be situated individually or as a group. Situating the microLEDs individually, or in a serial process is illustrated and described in more detail regarding FIGS. 9-11. Situating the microLEDs as a group is illustrated in more detail regarding FIG. 12.

FIGS. 9-11 illustrate, by way of example, respective diagrams of a process for individually attaching microLEDs 110 of a sparse array to pads 210. FIG. 9 illustrates, by way of example, a nozzle 990 dispensing a conductive adhesive 992 about pads 210. An arrow 996 indicates a direction of adhesive flow caused by a pressure. The nozzle 990 can be coupled to a motor, reservoir, a combination thereof, or the like, that causes the adhesive 992 to flow out the tip of the nozzle 990. The nozzle 990 can operate electrohydrodynamically to dispense the adhesive 992. Electrohydrodynamic dispensing is a known capability in which printing or controlled dispensing is achieved by driving a liquid with an electric field. Electrohydrodynamic dispensing is a near field jet printing technology using an electrostatic field. Electrohydrodynamic dispensing is a high-resolution printing technology that allows liquid to be dispensed only where desired, making it useful at the scale used in microLED adhesive printing of embodiments. The adhesive 992 can be dispensed onto each pad 210 so that it does not span the gap between directly adjacent pads 210. After dispensing the adhesive 992 on two or more pads 210, the pressure or electric field in the nozzle 990 can be turned off or reversed. Turning off the pressure means that there is no net pressure or electrical in the nozzle 990 so that it neither expels nor attracts external or internal objects. Reversing the pressure or electric field in the nozzle 990 means that the pressure or electrical field is set to attract an object external to the nozzle if the pressure or electric field in the nozzle 990 is currently set to expel an object internal to the nozzle or the opposite. The nozzle 990 can then be situated to “grab” a microLED 110 from a tray 994 or other organized collection of microLEDs 110.

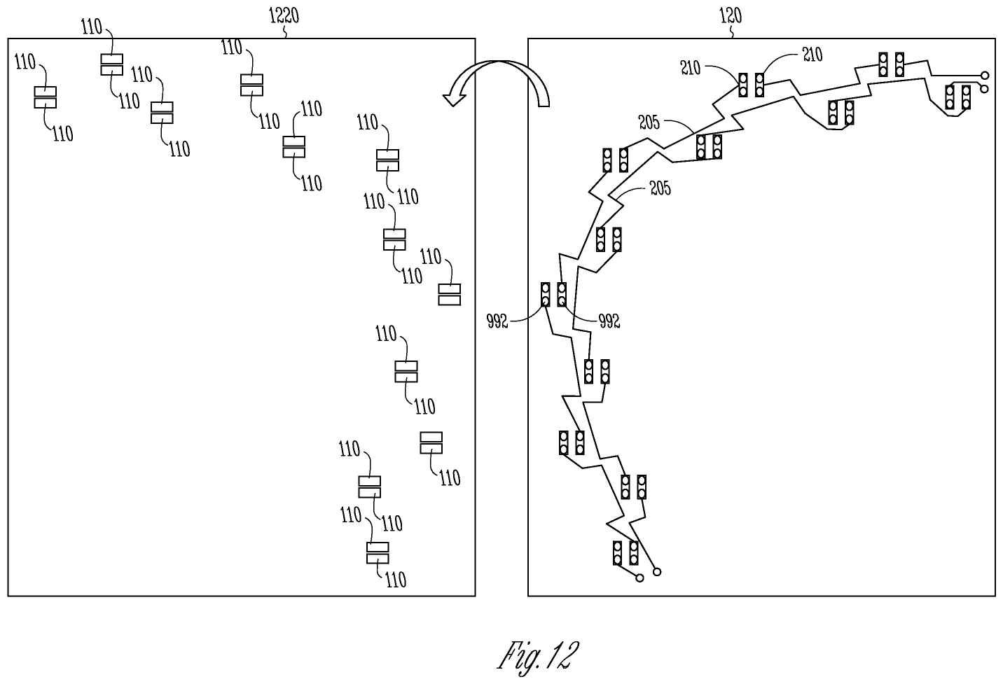

FIG. 10 illustrates, by way of example, the nozzle 990 situated to grab a microLED 110. To grab the microLED 110, the pressure or electrostatic field of the nozzle 990 can be configured to pull the microLED 110 to the tip of the nozzle 990. The electrostatic field or pressure can cause the microLED 110 to stick to the tip of the nozzle 990. The nozzle 990 can then traverse to a location directly over or in contact with exposed conductive adhesive 992. The pressure or electrostatic field in the nozzle 990 can then be turned off or reversed to expel the microLED 110 from the tip of the nozzle 990. The microLED 110 can be electrically connected to the pads 210 by the conductive adhesive 992.

FIG. 11 illustrates, by way of example, the microLED 110 attached to the pads 210 by the conductive adhesive 992. The process can then continue until all pads 210 are populated with microLEDs 110 from the tray 994. Instead of dispensing a single microLED 110 at a time, the nozzle 990 can grab two microLEDs 110 at a time and situate them on the same pads 210 concurrently. Instead of a single nozzle operating at a given time to dispense one or more microLEDs 110, multiple nozzles 990 can operate concurrently to dispense to different pads 210.

Instead of situating microLEDs 110 in a sort of serial fashion as described regarding FIGS. 9-11, the microLEDs 110 can be electrically connected as a complete group.

FIG. 12 illustrates, by way of example operations of a technique for concurrent mass electrical connection of the microLEDs 110 of a sparse array. The microLEDs 110 can be situated on a carrier 1220, such as can be similar to carrier 300. The carrier 1220 can include trenches, recesses, divots, posts, protrusions, or the like that help hold microLEDs 110 in preset locations. The preset locations of the microLEDs 110 can correspond to locations of pads 210 with conductive adhesive 992 on the backplane 120. The backplane 120 can be flipped over onto the carrier 1220 so that the pads 210 line up with corresponding microLEDs 110. The microLEDs 110 can be attached and electrically connected to corresponding pads 210 on the backplane 120. The carrier 1220 can be removed after the microLEDs 110 are bonded to the pads 210 by the adhesive 992. Removing the carrier 1220 leaves the microLEDs 110 attached to the backplane 120. The resulting array 600 is illustrated in FIG. 6.

FIG. 13 shows a plan view of an example laminated structure 315 (see also FIG. 3D) comprising a flexible transparent sheet (backplane 120) on which are disposed a plurality of inorganic microLEDs (microLED layer 310) and conductive paths configured to power the plurality of inorganic microLEDs, a transparent substrate 130, and a transparent sheet of adhesive 140 positioned between and bonded to the flexible transparent sheet and the transparent substrate. In the illustrated example the microLEDs and conductive paths are arranged to form a plurality of transparent microLED light sources for a plurality of eyepieces 100 (see also FIG. 1B) which may be cut from the laminated structure along the dashed lines defining the borders of the eyepieces in the FIG.

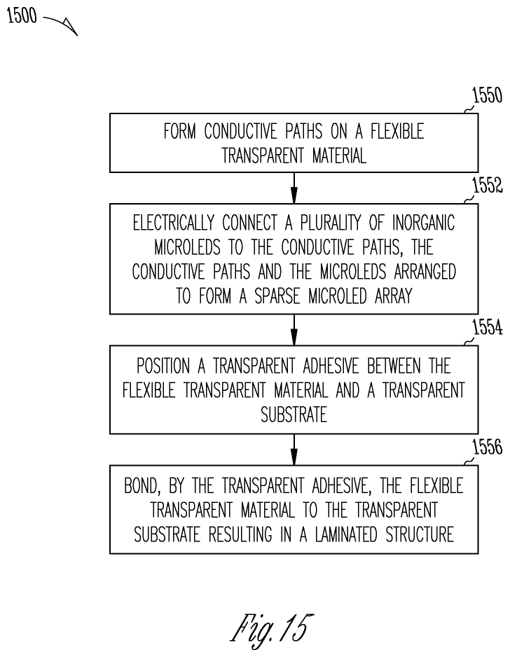

FIG. 14 shows an example variation in which a window 1400 for eyewear comprising two adjacent transparent microLED light sources 1405 (e.g., one for each eye) is cut from a laminated structure 1415 as shown in FIG. 13.

FIG. 15 illustrates, by way of example, a diagram of an embodiment of a method 1500 for forming a sparse microLED array, such as any of the sparse microLED arrays illustrated herein. The method 1500 as illustrated includes forming conductive paths on a flexible transparent material, at operation 1550; electrically connecting a plurality of inorganic microLEDs to the conductive paths, the conductive paths and the microLEDs arranged to form a sparse microLED array, at operation 1552; positioning a transparent adhesive between the flexible transparent material and a transparent substrate, at operation 1554; and bonding, by the transparent adhesive, the flexible transparent material to the transparent substrate resulting in a laminated structure, at operation 1556.

The conductive paths and the microLEDs can be arranged on the flexible transparent material to form independently operable and spatially separated sparse microLED arrays. The microLEDs can emit infrared light, visible light, or a combination thereof.

The method 1500 can further include bonding the transparent adhesive to the flexible transparent material prior to bonding the transparent adhesive to the transparent substrate. The method 1500 can further include bonding the transparent adhesive to the transparent substrate prior to bonding the transparent adhesive to the flexible transparent material. The method 1500 can further include disposing the conductive paths on the flexible transparent material. Forming the conductive paths on the flexible transparent material comprises electroplating conductive traces onto the flexible transparent material to form the conductive paths. Forming the conductive paths on the flexible transparent material can include coating the flexible transparent material with a transparent conductive film and segmenting the transparent conductive film to form trenches and define conductive paths electrically and physically separated by the trenches.

Electrically connecting the microLEDs to the conductive paths can include disposing the microLEDs on the flexible transparent material. Disposing the microLEDs on the flexible transparent material can include dispensing conductive adhesive at discrete locations on the conductive paths. Disposing the microLEDs on the flexible transparent material can include bonding, by the conductive adhesive, the microLEDs to the flexible transparent material.

Dispensing the conductive adhesive can include using an electrohydrodynamic nozzle to selectively print the conductive adhesive. Bonding the microLEDs to the flexible transparent material can include using the electrohydrodynamic nozzle to pick and place the microLEDs on the conductive adhesive.

The method 1500 can further include attaching the flexible transparent material to a carrier prior to disposing the microLEDs on the flexible transparent material. The method 1500 can further include detaching the flexible transparent material from the carrier after bonding the transparent adhesive to the flexible transparent material and to the transparent substrate to form the laminated structure.

The method 1500 can further include cutting from the laminated structure at least one transparent microLED light source comprising a sparse microLED array. The conductive paths and the microLEDs can be arranged on the flexible transparent material to form independently operable and spatially separated sparse microLED arrays. The method 1500 can further include cutting from the laminated structure transparent microLED light sources, each of the transparent microLED light sources comprising at least one of the independently operable and spatially separated sparse microLED arrays. The method 1500 can further include cutting from the laminated structure one or more transparent microLED light sources, each of the transparent microLED light sources comprising adjacent microLED arrays of the independently operable and spatially separated sparse microLED arrays. Each transparent microLED light source can be cut from the laminated structure in a shape of a lens or window for eyewear.

This disclosure is illustrative and not limiting. Further modifications will be apparent to one skilled in the art in light of this disclosure and are intended to fall within the scope of the appended claims.

### Examples and Additional Notes

Example 1 includes a method of forming one or more transparent micro light-emitting diode (microLED) light sources, the method comprising forming conductive paths on a flexible transparent material, electrically connecting a plurality of inorganic microLEDs to the conductive paths, the conductive paths and the microLEDs arranged to form a sparse microLED array, positioning a transparent adhesive between the flexible transparent material and a transparent substrate, and bonding, by the transparent adhesive, the flexible transparent material to the transparent substrate resulting in a laminated structure.
In Example 2, Example 1 further includes, wherein the conductive paths and the microLEDs are arranged on the flexible transparent material to form independently operable and spatially separated sparse microLED arrays.
In Example 3, at least one of Examples 1-2 further includes, wherein the microLEDs emit infrared light.
In Example 4, at least one of Examples 1-3 further includes bonding the transparent adhesive to the flexible transparent material prior to bonding the transparent adhesive to the transparent substrate.
In Example 5, at least one of Examples 1˜4 further includes bonding the transparent adhesive to the transparent substrate prior to bonding the transparent adhesive to the flexible transparent material.
In Example 6, at least one of Examples 1-5 further includes disposing the conductive paths on the flexible transparent material.
In Example 7, Example 6 further includes, wherein disposing the conductive paths on the flexible transparent material comprises electroplating conductive traces onto the flexible transparent material to form the conductive paths.
In Example 8, at least one of Examples 6-7 further includes, wherein disposing the conductive paths on the flexible transparent material comprises coating the flexible transparent material with a transparent conductive film and segmenting the transparent conductive film to form trenches and define conductive paths electrically and physically separated by the trenches.
In Example 9, at least one of Examples 6-8 further includes, wherein electrically connecting the microLEDs to the conductive paths includes disposing the microLEDs on the flexible transparent material.
In Example 10, Example 9 further includes, wherein disposing the microLEDs on the flexible transparent material comprises dispensing conductive adhesive at discrete locations on the conductive paths, and bonding, by the conductive adhesive, the microLEDs to the flexible transparent material.
In Example 11, Example 10 further includes, wherein dispensing the conductive adhesive includes using an electrohydrodynamic nozzle to selectively print the conductive adhesive.
In Example 12, Example 11 further includes, wherein bonding the microLEDs to the flexible transparent material includes using the electrohydrodynamic nozzle to pick and place the microLEDs on the conductive adhesive.
In Example 13, at least one of Examples 9-12 further includes attaching the flexible transparent material to a carrier prior to disposing the microLEDs on the flexible transparent material.
In Example 14, Example 13 further includes detaching the flexible transparent material from the carrier after bonding the transparent adhesive to the flexible transparent material and to the transparent substrate to form the laminated structure.
In Example 15, at least one of Examples 1-14 further includes cutting from the laminated structure at least one transparent microLED light source comprising a sparse microLED array.
In Example 16, at least one of Examples 1-15 further includes, wherein the conductive paths and the microLEDs are arranged on the flexible transparent material to form independently operable and spatially separated sparse microLED arrays, and the method further comprises cutting from the laminated structure transparent microLED light sources, each of the transparent microLED light sources comprising at least one of the independently operable and spatially separated sparse microLED arrays.
In Example 17, at least one of Examples 1-16 further includes, wherein the conductive paths and the microLEDs are arranged on the flexible transparent material to form independently operable and spatially separated sparse microLED arrays, and the method further comprises cutting from the laminated structure one or more transparent microLED light sources, each of the transparent microLED light sources comprising adjacent microLED arrays of the independently operable and spatially separated sparse microLED arrays.
In Example 18, at least one of Examples 16-17 further includes, wherein each transparent microLED light source is cut from the laminated structure in a shape of a lens or window for eyewear.
Example 19 includes a method of forming one or more transparent micro light-emitting diode (microLED) light sources, the method comprising providing a transparent laminated structure comprising a flexible transparent material on which are disposed a plurality of inorganic microLEDs and conductive paths configured to power the plurality of inorganic microLEDs, the conductive paths and the microLEDs arranged to form at least one sparse microLED array, a transparent substrate, and a transparent adhesive positioned between and bonded to the flexible transparent material and the transparent substrate, and cutting from the transparent laminated structure at least one transparent microLED light source comprising a sparse microLED array.
In Example 20, Example 19 further includes, wherein the conductive paths and the microLEDs are arranged on the flexible transparent material to form independently operable and spatially separated sparse microLED arrays after cutting, and the cutting breaks an electrical short between the spatially separated sparse microLED arrays making the sparse microLED arrays electrically separated.
Example 21 includes a transparent, light emitting, laminated structure comprising a flexible transparent material on which are disposed a plurality of inorganic microLEDs and conductive paths configured to power the plurality of inorganic microLEDs, the conductive paths and the microLEDs arranged to form at least one sparse microLED array, a transparent substrate, and a transparent adhesive positioned between and bonded to the flexible transparent material and the transparent substrate.
In Example 22, Example 21 further includes, wherein the microLEDs are infrared emitting microLEDs.
In Example 23, at least one of Examples 21-22 further includes, wherein the conductive paths and the microLEDs are arranged on the transparent flexible material to form two or more independently operable and spatially separated sparse microLED arrays.
In Example 24, at least one of Examples 21-23 further includes, wherein the microLEDs have side lengths in a plane of the laminated structure of about 2 microns to about 20 microns and are spaced apart from each other with center-to-center distances of greater than or equal to about 80 microns.
In Example 25, at least one of Examples 21-24 further includes, wherein the conductive paths comprise conductive traces having widths in a plane of the laminated structure of less than or equal to about 30 microns.
In Example 26, at least one of Examples 21-25 further includes, wherein the conductive paths comprise segmented portions of a conductive film disposed on the flexible transparent material.
In Example 27, Example 26 further includes trenches in the conductive film defining the segmented portions of the conductive film.
In Example 28, at least one of Examples 21-27 further includes, wherein the laminated structure has a shape of a lens or window for eyewear.
In Example 29, Example 28 further includes pairs of pads situated in an arc on the flexible transparent material.
In Example 30, Example 29 further includes, wherein the conductive paths electrically connect most proximate pairs of pads along the arc.
In Example 31, Example 30 further includes, wherein the conductive paths include a meandering square wave pattern and the pairs of pads are situated only at peaks of the meandering square wave pattern.
In Example 32, at least one of Examples 30-31 further includes, wherein the at least one sparse microLED array includes a first sparse microLED array and a second sparse microLED array, the conductive paths of the first microLED array include a meandering square wave pattern and the pairs of pads are situated only at peaks of the meandering square wave pattern, and the conductive paths of the second microLED array include a meandering square wave pattern and the pairs of pads are situated only at troughs of the meandering square wave pattern.
In Example 33, at least one of Examples 30-32 further includes, wherein the at least one sparse microLED array includes a first set of sparse microLED arrays situated to encompass, encircle, or surround a central point between the set of sparse microLED arrays.
In Example 34, Example 33 further includes, wherein the at least one sparse microLED array includes a second set of sparse microLED arrays situated to encompass, encircle, or surround a central point between the set of sparse microLED arrays and encompass, encircle, or surround the first set of sparse microLED arrays.
In Example 35, Example 34 further includes, wherein the first set of microLED arrays is controlled for flood and the second set of microLED arrays is controlled for glint.
Example 36 includes an eyewear device comprising a transparent, light emitting, laminated structure comprising a flexible transparent material on which are disposed a plurality of inorganic microLEDs and conductive paths configured to power the plurality of inorganic microLEDs, the conductive paths and the microLEDs arranged to form at least one sparse microLED array, a transparent substrate, and a transparent adhesive positioned between and bonded to the flexible transparent material and the transparent substrate, driver circuitry electrically coupled to the microLEDs, the driver circuitry configured to provide electrical power to the microLEDs, and a control device electrically coupled to the driver circuitry, the control device configured to provide electrical signals to the driver circuitry and control the electrical power provided by the driver circuitry.
In Example 37, Example 36 further includes, wherein the microLEDs are infrared emitting microLEDs and the electrical signals cause the microLEDs to provide infrared light for flood and glint.
In Example 38, Example 37 further includes, wherein the conductive paths and the microLEDs are arranged on the transparent flexible material to form two or more independently operable and spatially separated sparse microLED arrays.
In Example 39, at least one of Examples 36-38 further includes, wherein the laminated structure comprises pairs of pads situated in an arc on the flexible transparent material.
In Example 40, Example 39 further includes, wherein the conductive paths include a meandering square wave pattern and the pairs of pads are situated only at peaks of the meandering square wave pattern.

Although an embodiment has been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to indicate one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. As indicated herein, although the term “a” is used herein, one or more of the associated elements may be used in different embodiments. For example, the term “a processor” configured to carry out specific operations includes both a single processor configured to carry out all of the operations as well as multiple processors individually configured to carry out some or all of the operations (which may overlap) such that the combination of processors carry out all of the operations. Further, the term “includes” may be considered to be interpreted as “includes at least” the elements that follow.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method of forming one or more transparent micro light-emitting diode (microLED) light sources, the method comprising:
forming conductive paths on a flexible transparent material;
electrically connecting a plurality of inorganic microLEDs to the conductive paths, the conductive paths and the microLEDs arranged to form a sparse microLED array;
positioning a transparent adhesive between the flexible transparent material and a transparent substrate; and
bonding, by the transparent adhesive, the flexible transparent material to the transparent substrate resulting in a laminated structure.

2. The method of claim 1, wherein the conductive paths and the microLEDs are arranged on the flexible transparent material to form independently operable and spatially separated sparse microLED arrays.

3. The method of claim 1, wherein the microLEDs emit infrared light.

4. The method of claim 1, further comprising bonding the transparent adhesive to the flexible transparent material prior to bonding the transparent adhesive to the transparent substrate.

5. The method of claim 1, further comprising bonding the transparent adhesive to the transparent substrate prior to bonding the transparent adhesive to the flexible transparent material.

6. The method of claim 1, further comprising disposing the conductive paths on the flexible transparent material.

7. The method of claim 6, wherein disposing the conductive paths on the flexible transparent material comprises electroplating conductive traces onto the flexible transparent material to form the conductive paths.

8. The method of claim 6, wherein disposing the conductive paths on the flexible transparent material comprises coating the flexible transparent material with a transparent conductive film and segmenting the transparent conductive film to form trenches and define conductive paths electrically and physically separated by the trenches.

9. The method of claim 6, wherein electrically connecting the microLEDs to the conductive paths includes disposing the microLEDs on the flexible transparent material.

10. The method of claim 9, wherein disposing the microLEDs on the flexible transparent material comprises:
dispensing conductive adhesive at discrete locations on the conductive paths; and
bonding, by the conductive adhesive, the microLEDs to the flexible transparent material.

11. The method of claim 10, wherein dispensing the conductive adhesive includes using an electrohydrodynamic nozzle to selectively print the conductive adhesive.

12. The method of claim 11, wherein bonding the microLEDs to the flexible transparent material includes using the electrohydrodynamic nozzle to pick and place the microLEDs on the conductive adhesive.

13. The method of claim 9, further comprising attaching the flexible transparent material to a carrier prior to disposing the microLEDs on the flexible transparent material.

14. The method of claim 13, further comprising detaching the flexible transparent material from the carrier after bonding the transparent adhesive to the flexible transparent material and to the transparent substrate to form the laminated structure.

15. The method of claim 1, comprising cutting from the laminated structure at least one transparent microLED light source comprising a sparse microLED array.

16. The method of claim 1, wherein:
the conductive paths and the microLEDs are arranged on the flexible transparent material to form independently operable and spatially separated sparse microLED arrays, and
the method further comprises cutting from the laminated structure transparent microLED light sources, each of the transparent microLED light sources comprising at least one of the independently operable and spatially separated sparse microLED arrays.

17. The method of claim 1, wherein:
the conductive paths and the microLEDs are arranged on the flexible transparent material to form independently operable and spatially separated sparse microLED arrays, and
the method further comprises cutting from the laminated structure one or more transparent microLED light sources, each of the transparent microLED light sources comprising adjacent microLED arrays of the independently operable and spatially separated sparse microLED arrays.

18. The method of claim 16, wherein each transparent microLED light source is cut from the laminated structure in a shape of a lens or window for eyewear.

19. A method of forming one or more transparent micro light-emitting diode (microLED) light sources, the method comprising:
providing a transparent laminated structure comprising:
a flexible transparent material on which are disposed a plurality of inorganic microLEDs and conductive paths configured to power the plurality of inorganic microLEDs, the conductive paths and the microLEDs arranged to form at least one sparse microLED array;
a transparent substrate; and
a transparent adhesive positioned between and bonded to the flexible transparent material and the transparent substrate; and
cutting from the transparent laminated structure at least one transparent microLED light source comprising a sparse microLED array.

20. The method of claim 19, wherein:
the conductive paths and the microLEDs are arranged on the flexible transparent material to form independently operable and spatially separated sparse microLED arrays after cutting, and
the cutting breaks an electrical short between the spatially separated sparse microLED arrays making the sparse microLED arrays electrically separated.
